(19) United States
(12) Patent Application Publication
(10) Pub. No.: US 2012/0237789 A1
(43) Pub. Date: Sep. 20, 2012

(54) HIGH YIELD STRENGTH LIGHTWEIGHT POLYMER-METAL HYBRID ARTICLES

(75) Inventors: Andrew Wang, Toronto (CA); Nandakumar Nagarajan, Burlington (CA); Klaus Tomantschger, Mississauga (CA); Mioara Neacsu, Maple (CA)

(73) Assignee: INTEGRAN TECHNOLOGIES INC., Mississauga (CA)

(21) Appl. No.: 13/279,731

(22) Filed: Oct. 24, 2011

Related U.S. Application Data
(60) Provisional application No. 61/442,837, filed on Mar. 15, 2011.

(51) Int. Cl. B32B 15/08; C23C 16/52; B05D 1/18; C25D 5/56; B32B 15/082; B32B 15/09; B32B 15/092; B32B 15/095; B32B 15/098; B32B 5/02; B32B 5/16; C23C 16/06; B32B 15/088; B82Y 30/00

(52) U.S. Cl. 428/626; 427/250; 427/8; 427/443.1; 205/164; 428/457; 428/35.8; 428/446; 428/426; 428/413; 428/422; 428/458; 428/460; 428/425.8; 428/412; 428/463; 428/462; 428/332; 428/408; 977/742

(57) ABSTRACT

A metal-clad polymer article includes a polymeric material with or without particulate addition. The polymeric material defines a permanent substrate. A metallic material covers at least part of a surface of the polymeric material. The metallic material has a microstructure which, at least in part, is at least one of fine-grained with an average grain size between 2 and 5,000 nm and amorphous. The metallic material has an elastic limit between 0.2% and 15%. At least one intermediate layer can be provided between the polymeric material and the metallic material. A stress on the polymeric material, at a selected operating temperature, reaches at least 60% of its ultimate tensile strength at a strain equivalent to the elastic limit of said metallic material.

The present application claims priority to U.S. Provisional Patent Application Ser. No. 61/442,837 filed on Feb. 15, 2011, which is incorporated herein in its entirety.

### FIELD OF THE INVENTION

Exemplary embodiments herein relate to high strength to weight polymer-metal hybrid articles comprising polymeric materials and, at least in part, high strength, fine-grained (average grain-size: 2-5,000 nm) and/or amorphous metallic material. Suitable material combinations are chosen such that the resulting polymer-metal hybrid articles exhibit increased stiffness while maintaining high yield strengths at low thicknesses of the clad metal article, thereby minimizing the part weight or part density. The lightweight metal-clad polymer articles taught herein specifically optimize the load bearing contribution from both the metallic and the polymeric materials and are particularly suitable for structural applications.

### BACKGROUND OF THE INVENTION

Metal/polymer hybrid articles for structural applications are gaining increased interest for use in commercial applications requiring lightweight parts. Nanocrystalline, fine-grained and/or amorphous metal coatings are increasingly utilized for structural applications whereas prior art metallized polymers have previously been focused on decorative and wear resistant coatings as well as EMI shielding applications, medical devices and for coatings for use in high-temperature applications. Metal-polymer laminates have also been disclosed for use as light weight replacements for sheet steel in structural applications, as well as in sound or vibration damping applications.

Hurley in U.S. Pat. No. 3,868,229 (1976) discloses a process for a decorative nickel chrome coating on ABS wherein, the plated polymer is characterized by good appearance, excellent resistance to thermal cycling and corrosive media. The plated polymer was not determined to have any enhanced structural properties.

Donovan et al in U.S. Pat. No. 6,468,672 (2002) also disclose a decorative chromium plating process on a polymer substrate, which provides a lustrous decorative finish with enhanced thermal cycling and corrosion resistance characteristics, but no structural enhancements compared with the bare polymer.

Lutz in U.S. Pat. No. 4,601,941 (1986) discloses a metal-polymer-metal structural laminate having property advantages including light-weight, good adhesion between polymer and metal, and high stiffness. The metal sheets are pressed onto the polymer at temperatures higher than the melting temperature of the polymer. Adhesion values were obtained by lap-shear testing.

Imanaka in U.S. Pat. No. 4,268,570 (1981) discloses metal coated polymer products which have excellent properties such as stiffness, plasticity, processibility and an appealing appearance, which could be used as substitutes for metallic products. The metallized layer of chromium is prepared by vacuum metallization.

Boesman in US 2003/0008126 (2003) discloses a method to reinforce stiff composite articles, comprising of metallic elements that run parallel to each other and through the composite structure. The reinforcing structure is stated to improve the bending properties of the composite.

In terms of the process of bonding of metal to polymer, the prior art describes numerous processes for metalizing polymers to render them suitable for metal deposition by conditioning the substrate's surface to insure metal deposits adequately bond thereto resulting in durable and adherent metal coatings. Known methods for the application of the metal coating on the polymers include vapor deposition approaches and solution based approaches. One preferred substrate conditioning/activation process is chemical etching.

Scheckenbach in U.S. Pat. No. 6,074,740 (2000) describes a process for metalizing polymer mixtures containing a thermoplastic and a filler. Examples of thermoplastic polymers included PEEK, PBT, Hostaflon, ULTEM polyimide and Torlon. The metallization process is either vapor deposition process or sputtering. The metallization layer was around 240 nm.

Stevenson in U.S. Pat. No. 4,552,626 (1985) describes a process for metal plating filled thermoplastic resins such as Nylon-6®. The filled resin surface to be plated is cleaned and rendered hydrophilic and preferably deglazed by a suitable solvent or acid. At least a portion of the filler in the surface is removed, preferably by a suitable acid. Thereafter electroless plating is applied to provide an electrically conductive metal deposit followed by applying at least one metallic layer by electroplating to provide a desired wear resistant and/or decorative metallic surface.

Leech in U.S. Pat. No. 4,054,693 (1977) discloses processes for the activation of resinous materials with a composition comprising water, permanganate ion and manganate ion at a pH in the range of 11 to 13 exhibiting superior peel strengths following electroless metal deposition.

McCrea in US 2010/0300889, assigned to the same assignee as the present application, describes a novel activation/etch method for conductive polymer substrates and conductive polymer composite substrates to achieve good adhesion to subsequently applied coatings. The method involves anodically polarizing conductive polymers/polymer composites in aqueous etching solutions.

Various patents address the fabrication of articles containing fine-grained metals, alloys and metal matrix composites (MMCs) for a variety of applications:

Erb in U.S. Pat. No. 5,352,266 (1994), and U.S. Pat. No. 5,433,797 (1995), both assigned to the same assignee as the present application, describe a process for producing nanocrystalline materials, particularly nanocrystalline nickel. The nanocrystalline material is electrodeposited onto the cathode in an aqueous acidic electrolytic cell by application of a pulsed current.

Palumbo in U.S. Ser. No. 10/516,300 (2002) and DE 10,288,323 (2005), both assigned to the same assignee as the present application, disclose a process for forming coatings or freestanding deposits of nanocrystalline metals, metal alloys or metal matrix composites. The process employs tank, drum plating or selective plating processes using aqueous electrolytes and optionally a non-stationary anode or cathode. Nanocrystalline metal matrix composites are disclosed as well.

Palumbo in U.S. Pat. No. 7,320,832 (2008) and U.S. Pat. No. 7,824,774 (2010), both assigned to the same assignee as the present application, disclose means for matching the coefficient of thermal expansion (CTE) of fine-grained metallic coating to the substrate by adjusting the composition of the alloy and/or by varying the chemistry and volume fraction of particulates embedded in the coating. The fine-grained metallic coatings are particularly suited for strong and lightweight articles, precision molds, sporting goods, automotive parts and components exposed to thermal cycling and include polymeric substrates. Maintaining low CTEs (<25×10⁻⁶ K⁻¹) and matching the CTEs of the fine-grained metallic coating with the CTEs of the substrate minimizes dimensional changes during thermal cycling and preventing delamination.

Palumbo in U.S. Pat. No. 7,354,354 (2008) and U.S. Pat. No. 7,553,553 (2010), both assigned to the same assignee as the present application, disclose lightweight articles comprising a polymeric material at least partially coated with a fine-grained metallic material. The fine-grained metallic material has an average grain size of 2 nm to 5,000 nm, a thickness between 25 micron and 5 cm, and a hardness between 200 VHN and 3,000 VHN. The lightweight articles are strong and ductile and exhibit high coefficients of resilience and a high stiffness and are particularly suitable for a variety of applications including aerospace and automotive parts, sporting goods, and the like.

Elia in WO2009045416 (2009) discloses a vehicular electrical or electronic housing, comprising of an organic polymer coated at least in part by metal, wherein the metal possesses a flexural modulus at least twice that of the polymer. Preferred glass transition temperatures are disclosed for the polymer, but no mention is made of any crystallinity requirements for the polymer.

Elia in WO2009045431 (2009), co-owned by the same assignee as the present application, disclose a structural member for cell phones, comprising of a synthetic resin composition which is covered in part by a metal, wherein the metal possesses a flexural modulus at least twice that of the polymer.

Tomantschger in US 2009/0159451 (2009), assigned to the same assignee as the present application, discloses variable property deposits (graded and/or layered) of fine-grained and amorphous metallic materials, optionally containing solid particulates, on a variety of substrates, including polymeric, for sporting good, cell phones, automotive components, gun barrels and orthopedic applications.

Tomantschger in US 2010/0304065, assigned to the same assignee as the present application, describes metal-clad polymer articles containing structural fine-grained and/or amorphous metallic coatings/layers optionally containing solid particulates dispersed therein. The metallic coatings are particularly suited for strong and lightweight articles, precision molds, sporting goods, automotive parts and components exposed to thermal cycling although the coefficient of linear thermal expansion (CLTE) of the metallic layer and the substrate are mismatched. The interface between the metallic layer and the polymer is suitably pretreated to withstand thermal cycling without failure.

### SUMMARY OF THE INVENTION

The present disclosure focuses on designing lightweight structural metal-clad polymer components by properly selecting the metallic material and suitably matching its mechanical properties at the appropriate application temperature or temperature range with an appropriate polymer rather than arbitrarily applying a metallic material to a polymer substrate. One design feature of the present disclosure is determining when the metallic coating reaches its elastic limit or yield point and selecting a suitable polymer which, at the yield point of the metallic material, reaches a significant fraction of its ultimate tensile strength (UTS) and contributes to the overall strength of the metal-clad polymer article. Thus, the present disclosure focuses on the selection of the optimal metallic material and polymer combinations to derive at lightweight components with extremely high specific load carrying capability. Important components of the teaching of the present disclosure are the selection of:
(i) a strong, fine-grained and/or amorphous metallic coating with a high elastic limit; and
(ii) a polymer with high yield strength that is stiff enough and capable of carrying high loads reversibly when the metal coating reaches its yield point.

The inventive material selection and property combination maximizes the advantage of the properties of both materials. More specifically, the material selection can be defined as the combination of metallic and polymeric materials which result in an enhancement in the load bearing capacity of the resulting hybrid article at a lower metal and/or lower hybrid thickness compared to prior art un-optimized metal-clad polymer articles, and thereby provides a lower weight alternative. Keeping the thickness of the clad metal layer to a minimum is also advantageous from a cost and weight perspective.

It is an objective of the present disclosure to provide lightweight metal-clad polymer hybrid articles by selecting a metallic material having a microstrcture which, at least in part, is one of fine-grained and amorphous and with an elastic limit of ≧0.25%, preferably ≧0.4%, more preferably ≧0.5%, more preferably ≧0.6%, more preferably ≧0.7%, and even more preferably ≧1%.

The inventive design formula to achieve the lightweight metal-clad polymer article selects a polymer which, at the elastic limit of the metallic material, i.e., when the metallic material reaches its yield strain (i.e., elastic limit) at room temperature, and/or the desired operating temperature and/or maximum operating temperature, the stress on the polymer is ≧50% of the polymer's ultimate tensile strength (the design ratio); preferably ≧60%, more preferably ≧70%, more preferably ≧80%, and even more preferably >90%; and/or the stress on the polymer is ≧50 MPa, preferably ≧60 MPa, more preferably ≧100 MPa, and even more preferably ≧175 MPa.

It is thus an objective of the present disclosure to provide metal-clad polymer hybrids wherein, at the maximum and/or predominant operating temperature and/or the entire operating temperature range of the article, when the metallic material or layer reaches its yield strain, the stress on the polymer reaches ≧50% of the polymer's ultimate tensile strength, preferably ≧60%, more preferably ≧70%, more preferably ≧75%, more preferably ≧80%, and even more preferably ≧90% of its ultimate tensile strength.

It is an objective of the present disclosure to provide lightweight metal-clad polymer hybrid articles wherein, at room temperature and/or the maximum operating temperature and/or predominant operating temperature and/or the entire operating temperature range of the article, the stress on the article is ≧150 MPa, preferably ≧175 MPa, more preferably ≧200 MPa, more preferably ≧225 MPa, ≧250 MPa, and even more preferably ≧275 MPa before the article yields and irreversibly deforms.

Another objective of the present disclosure is to replace parts or components made of lightweight metals, e.g., metals and alloys comprising Al, Mg, Ti, Sc, including, but not limited to Aluminum 6061-T6 or CP-2 Titanium, with an inventive metal-clad polymer hybrid component that will have an enhanced load-bearing capacity, as well as remain lighter than the corresponding aluminum part.

It is therefore another objective of the present disclosure to provide lightweight metal-clad polymer hybrid articles by selecting a polymer which, at a tensile strain of 0.4% (representing the elastic limit of A1 6061-T6), at room temperature, and/or the desired operating temperature and/or maximum operating temperature, exhibits a stress of ≧30% of the polymer's ultimate tensile strength, preferably ≧50%, preferably ≧60%, preferably ≧70%, more preferably ≧80%, and even more preferably ≧90% of the polymer's ultimate tensile strength; and/or the stress on the polymer is ≧50 MPa, preferably ≧60 MPa, preferably ≧65 MPa, preferably ≧80 MPa, preferably ≧100 MPa, preferably ≧125 MPa; preferably ≧175 MPa, more preferably ≧185 MPa, and still more preferably ≧200 MPa while having a density of ≦4.5 g/cm³.

It is another objective of this disclosure to provide lightweight metal-clad polymer articles, wherein the metallic material cladding thickness is adjusted such that the overall average density of metal-clad article is equal to or lower than the density of A1 6061-T6 (2.7 g/cm³), preferably by ≧5%, more preferably by ≧10% and even more preferably by ≧20%.

Another objective of the present disclosure is to provide metal-clad polymer articles which retain a high portion of their room temperature strength and stiffness at elevated service temperatures, up to 150° C., specifically ≧60% of their room temperature strength at 90° C., more preferably ≧75% of their room temperature strength at 90° C., and/or ≧50% of their room temperature strength at 120° C., and more preferably ≧65% of their room temperature strength at 120° C.

Another objective of the present disclosure is to provide metal-clad polymer articles by suitably selecting polymers, which at the component service temperature and/or maximum operating temperature, retain ≧60%, preferably ≧70%, and more preferably ≧80% of its room temperature modulus and strength.

Another objective of the present disclosure is to provide metal-clad polymer articles by suitably selecting polymers which are ≧20%, preferably ≧30%, and more preferably ≧40% crystalline by weight or volume.

It is an objective of the present disclosure to provide inventive design conditions which result in an enhancement of the load bearing capacity of the metal-clad polymer hybrid article when compared to the polymer article not containing the fine-grained and/or amorphous metallic material; or when compared to an article containing a coarse-grained metallic material, or articles containing the fine-grained and/or amorphous metallic material without applying the optimized, matching criteria of the instant invention.

It is an objective of the present disclosure to minimize the thickness of the metallic material required to achieve the design value of the load bearing capacity of the metal-clad polymer hybrid article. Conventional design of metal-clad polymer articles is typically based on altering the coating thickness of the metallic layer in order to achieve the target tensile strength, flexural strength or stiffness. By designing the part or article based on the stress on the polymer when the metal reaches its yield strain, more effective use of each material's properties are utilized, resulting in thinner coatings and reduced cost and weight. Such optimized, high yield-strength metal-polymer hybrid articles are particularly suited for use in structural applications.

Due to their low cost and ease of processing/shaping by various means, polymeric materials, which are optionally filled with or reinforced, are widely used. Applying metallic coatings or layers to the surfaces of polymer parts is of considerable commercial importance because of the desirable properties obtained by combining polymers and metals. Metallic materials, layers and/or coatings are strong, hard tough and aesthetic and can be applied to polymer substrates by various low temperature commercial process methods including electroless deposition techniques and/or electro-deposition. The metal deposits must adhere well to the underlying polymer substrate even in corrosive environments and when subjected to thermal cycling and loads, as encountered in outdoor or industrial service.

It is an objective of the present disclosure to provide high-strength metal-polymer hybrid articles with the lowest possible clad-metal thickness for a given design load, having enhanced stiffness, breaking strength under tensile, flexural and torsional loading, exhibiting excellent adhesion, pull-off strength, peel strength, shear strength and thermal cycling performance for use in structural applications, e.g., in automotive, aerospace and defense applications, industrial components, electronic equipment or appliances and sporting goods, molding applications and medical applications.

It is an objective of the present disclosure to provide high-strength metal-polymer hybrid articles, for:
(i) applications requiring cylindrical objects including gun barrels; shafts, tubes, pipes and rods for use as golf, arrow, skiing and hiking pole shafts; various drive shafts; fishing poles; baseball bats, bicycle frames, ammunition casings, wires and cables and other cylindrical or tubular structures for use in commercial goods including gun barrels, optical housings for guns, rifles, and suppressors for firearms with projectiles at subsonic speeds;
(ii) medical equipment including orthopedic prosthesis and surgical tools;
(iii) sporting goods including golf shafts, heads and faceplates; lacrosse sticks; hockey sticks; skis and snowboards as well as their components including bindings; racquets for tennis, squash, badminton; bicycle parts;
(iv) components and housings for electronic equipment including laptops; hand-held devices including cell phones; personal digital assistants (PDAs) devices; MP3 players and BlackBerry®-type devices; cameras and other image recording devices as well as TVs; electrical connectors;
(v) automotive components including heat shields; cabin components including seat parts, steering wheel and armature parts; fluid conduits including air ducts, fuel rails, turbocharger components, oil, transmission and brake parts, fluid tanks and housings including oil and transmission pans; cylinder head covers; spoilers; grill-guards and running boards; brake, transmission, clutch, steering and suspension parts; brackets and pedals; muffler components; wheels; brackets; vehicle frames; spoilers; fluid pumps such as fuel, coolant, oil and transmission pumps and their components; housing and tank components such as oil, transmission or other fluid pans including gas tanks; electrical and engine covers;
(vi) industrial/consumer products and parts including linings on hydraulic actuator, cylinders and the like; drills; files; knives; saws; blades; sharpening devices and other cutting, polishing and grinding tools; housings; frames; hinges; sputtering targets; antennas as well as electromagnetic interference (EMI) shields;
(vii) molds and molding tools and equipment;
(viii) aerospace parts including wings; wing parts including flaps and access covers; structural spars and ribs; propellers; rotors; rotor blades; aircraft engine components; rudders; covers; housings; connector bodies; fuselage parts; nose cones landing gear; lightweight cabin parts; cryogenic storage tanks; ducts and interior panels; and
(ix) military products including ammunition, armor as well as firearm components.

It is an objective of the present disclosure to provide metal-clad-polymer hybrids which provide high strength and stiffness under tensile, flexural and torsional loading, for a range of service temperatures, ranging from −40° C. to 200° C., for use in structural applications.

It is an objective of the present disclosure to provide high-strength metal-polymer hybrid articles, for:
(i) applications requiring cylindrical objects including gun barrels; shafts, tubes, pipes and rods for use as golf, arrow, skiing and hiking pole shafts; various drive shafts; fishing poles; baseball bats, bicycle frames, ammunition casings, wires and cables and other cylindrical or tubular structures for use in commercial goods including gun barrels, optical housings for guns, rifles, and suppressors for firearms with projectiles at subsonic speeds;
(ii) medical equipment including orthopedic prosthesis and surgical tools;
(iii) sporting goods including golf shafts, heads and faceplates; lacrosse sticks; hockey sticks; skis and snowboards as well as their components including bindings; racquets for tennis, squash, badminton; bicycle parts;
(iv) components and housings for electronic equipment including laptops; hand-held devices including cell phones; personal digital assistants (PDAs) devices; MP3 players and BlackBerry®-type devices; cameras and other image recording devices as well as TVs; electrical connectors;
(v) automotive components including heat shields; cabin components including seat parts, steering wheel and armature parts; fluid conduits including air ducts, fuel rails, turbocharger components, oil, transmission and brake parts, fluid tanks and housings including oil and transmission pans; cylinder head covers; spoilers; grill-guards and running boards; brake, transmission, clutch, steering and suspension parts; brackets and pedals; muffler components; wheels; brackets; vehicle frames; spoilers; fluid pumps such as fuel, coolant, oil and transmission pumps and their components; housing and tank components such as oil, transmission or other fluid pans including gas tanks; electrical and engine covers;
(vi) industrial/consumer products and parts including linings on hydraulic actuator, cylinders and the like; drills; files; knives; saws; blades; sharpening devices and other cutting, polishing and grinding tools; housings; frames; hinges; sputtering targets; antennas as well as electromagnetic interference (EMI) shields;
(vii) molds and molding tools and equipment;
(viii) aerospace parts including wings; wing parts including flaps and access covers; structural spars and ribs; propellers; rotors; rotor blades; aircraft engine components; rudders; covers; housings; connector bodies; fuselage parts; nose cones landing gear; lightweight cabin parts; cryogenic storage tanks; ducts and interior panels; and
(ix) military products including ammunition, armor as well as firearm components.

It is an objective of the present disclosure to provide metal-clad-polymer hybrids which provide high strength and stiffness under tensile, flexural and torsional loading, for a range of service temperatures, ranging from −40° C. to 200° C., for use in structural applications.

It is an objective of the present disclosure to provide a metal-clad polymer article whose properties, for a given article weight and/or density, are uniquely achieved only by the combination of the specific metal and the specific polymer, and not individually by any of the components.

It is an objective of the present disclosure to provide a metallic coating/layer selected from the group of amorphous, fine-grained metal, metal alloy or metal matrix composites. The person skilled in the art will know that within the operating temperature range of −40° C. to 200° C., unlike in the case of polymeric materials, and unlike in the case of aluminum and titanium alloys, there is hardly a noticeable change in the stress-strain behavior of the metallic material selected. The metallic coating/layer is applied to the polymer substrate by a suitable metal deposition process. Such metal deposition processes include low temperature processes, i.e., processes operating well below the softening and/or melting temperature of the polymer substrates, selected from the group of electroless deposition, electrodeposition, physical vapor deposition (PVD), chemical vapor deposition (CVD), cold spraying and gas condensation. The metallic material represents between 0.1% and 99% of the total weight or volume of the article, preferably between 1 and 25% of the total weight or volume of the article.

It is an objective of the present disclosure to provide a fine-grained and/or amorphous metallic coating wherein the coating consists of multiple layers bonded together by any of the aforementioned processes. The multiple layers may be of the same metal or alloy, but with differing physical or mechanical properties. The multiple layers may also be of an alloy, but with differing alloy compositions. The multiple layers may also be of different metals or different alloys. In addition to the high strength and stiffness benefits that may be attained, the multiple layers in the coating may be applied to enhance the coating's functional properties such as corrosion resistance. Alternatively, the multiple layers may also enhance the aesthetic appearance of a part or object to be coated.

The metallic and polymeric material can also be optionally graded, e.g., by chemical composition, microstructure, physical properties etc. Also in keeping within the scope of the present disclosure at least one of the components of the article can be layered and the layers can be uniform in properties and/or graded.

It is an objective of the present disclosure to provide a metal-clad polymer article comprising a suitably shaped or molded polymer component comprising suitable polymeric resins or polymeric composites. Also being within the scope of the present disclosure are polymer substrates which are open and closed cell foams, cellular molded structures, other honeycomb type structures and trusses. The person skilled in the art will know that these structures may be provided with an outer surface layer for metal deposition.

It is an objective of this disclosure to provide a fine-grained and/or amorphous metallic layer comprising one or more elements selected from the group consisting of Ag, Al, Au, Co, Cr, Cu, Fe, Ni, Mo, Mn, Pb, Pd, Pt, Rh, Ru, Sn, Ti, W, Zn and Zr optionally containing particulate additions.

It is an objective of the present disclosure to utilize the enhanced mechanical strength and wear properties of fine-grained metallic coatings/layers with an average grain size between 1 and 5,000 nm and/or amorphous coatings/layers and/or metal matrix composite coatings. Metal matrix composites (MMCs) in this context are defined as particulate matter embedded in a fine-grained and/or amorphous metal matrix. MMCs can be produced, e.g., in the case of using an electroless plating or electroplating process by suspending particles in a suitable plating bath and incorporating particulate matter into the deposit by inclusion or, e.g., in the case of cold spraying by adding non-deformable particulates to the powder feed, or by forming particles in-situ from a plating bath at the deposition electrode

It is an objective of the present disclosure to apply the fine-grained and/or amorphous metallic coating to at least a portion of the surface of a part made substantially of polymer(s) or polymer composites, after optionally metallizing the surface (layer thickness ≦5 micron, preferably ≦1 micron) with a thin layer of nickel, copper, silver or the like for the purpose of enhancing the electrical conductivity of the substrate surface. The fine-grained and/or amorphous coating is always substantially thicker (≧10 micron) than the metallizing layer.

According to this disclosure patches or sleeves which are not necessarily uniform in thickness can be employed in order to, e.g., enable a metallic thicker coating on selected sections or areas of articles particularly prone to heavy use.

It is an objective of this disclosure to provide lightweight polymer/metal-hybrid articles with increased strength, stiffness, durability, wear resistance, thermal conductivity and thermal cycling capability.

It is an objective of this disclosure to provide polymer-metal hybrid articles, which, at service temperatures higher than room temperature, retain more strength and stiffness, than articles made of only the polymer.

It is an objective of this disclosure to provide polymer-metal hybrids which have a higher fatigue limit than the equivalent volume and shape polymer article, as well as conventional coarse-grained metal-polymer hybrids of the similar chemical composition and overall weight, preferably at least 100 cycles and higher at 100% of the design (i.e., rated) and/or yield stress of the article, and more preferably ≧1000 cycles at 80% of the design and/or yield stress of the article, and more preferably, ≧10,000 cycles and higher at 60% of the design and/or yield stress, and more preferably ≧100,000 cycles or higher at 40% of the design and/or yield stress, and even more preferably >1 million cycles at 20% of the design and/or yield stress, and a ‘run-off’, implying no fatigue failures, preferably at 10 million cycles or more.

It is also an objective of the present disclosure to provide polymer-metal hybrids which have a higher residual strength after cyclic loading than the equivalent polymer article, and conventional metal-polymer hybrids of a similar chemical composition.

It is an objective of this disclosure to provide polymer articles, coated with fine-grained and/or amorphous metallic layers that are stiff, lightweight, resistant to abrasion, resistant to permanent deformation, do not splinter when cracked or broken and are able to withstand thermal cycling without degradation.

It is an objective of the present disclosure to provide polymer-metal hybrid articles wherein the polymer or metal fully encapsulates the other material. Alternatively, polymer-metal hybrid articles selectively having metal patches applied to certain areas only, e.g., in form of patches, sleeves, are well within the scope of this invention.

It is an objective of this disclosure to at least partially coat the inner or outer surface of parts, including complex shapes, with fine-grained and/or amorphous metallic materials that are strong, lightweight, have high stiffness (e.g. resistance to deflection and higher natural frequencies of vibration) and are able to withstand thermal cycling without degradation.

Accordingly, the present disclosure is directed to a high yield-strength metal-clad polymer article containing:
(i) a polymeric material with or without particulate addition, said polymeric material defining a permanent substrate, and
(ii) a metallic material covering at least part of the surface of said polymeric material, said metallic material having a microstructure which, at least in part, is at least one of fine-grained with an average grain size between 2 and 5,000 nm and amorphous, said metallic material having an elastic limit between 0.2% and 15%; and
(iii) with or without at least one intermediate layer between said polymeric material and said metallic material; and
(iv) wherein said polymeric material, at the operating temperature, reaches at least 60% of its ultimate tensile strength at the strain equivalent to the elastic limit of said metallic material.

Accordingly, in another embodiment, the present disclosure is directed to a high yield-strength metal-clad polymer article containing:
(i) a polymeric material with or without particulate addition, said polymeric material defining a permanent substrate, and
(ii) a metallic material covering at least part of the surface of said polymeric material, said metallic material having a microstructure which, at least in part, is at least one of fine-grained with an average grain size between 1 and 5,000 nm and amorphous, and
(iii) with or without at least one intermediate layer between said polymeric material and said metallic material; and
(iv) wherein, at a selected operating temperature, the stress on said polymeric material at a strain of 0.4% is at least 65 MPa.

Accordingly, in yet another embodiment, the present disclosure is directed to a method for providing a high yield-strength metal-clad polymer article by:
(i) providing a metallic material having a microstructure which, at least in part, is at least one of fine-grained with an average grain size between 2 and 5,000 nm and amorphous; and
(ii) selecting a polymeric material which, at the strain equivalent to the elastic limit of the metallic material, has a stress of at least 60% of its UTS at the operating temperature; and
(iii) applying the metallic material to at least part of the polymer substrate to form a light-weight article.

### DEFINITIONS

As used herein the term “ultimate tensile strength” (UTS) of a material is defined as the maximum tensile stress carried by the material prior to failure, measured at a specific temperature.

As used herein the term “stress-strain curve” refers to a curve generated during tensile testing of a material sample and the “stress-strain curve” is a graphical representation of the relationship between the applied stress, derived from measuring the load applied on the sample, and the strain, derived from measuring the deformation of the sample, i.e., the elongation, compression, or distortion.

As used herein the term “yield strength” or “yield point” of a material is defined as the stress at which a material begins to deform plastically, i.e., irreversibly (i.e., the maximum stress that can be applied without exceeding a specified value of permanent strain).

As used herein the “elastic limit” is defined as the lowest stress where permanent deformation occurs (i.e., the maximum stress that can be applied without resulting in permanent deformation when unloaded), and “percent elongation” means the strain at fracture, expressed as a percentage, and is a measure of ductility.

As used herein the term “stiffness” means the resistance of an elastic body to deflection or deformation by an applied force.

As used herein “fatigue” is the progressive and localized structural damage that occurs when a material is subjected to cyclic loading and the “fatigue life” is the number of stress cycles that a specimen can sustain before failure.

As used herein, the terms “metal-coated polymer article” and “metal-clad polymer article” mean an item which contains at least one polymer substrate material and at least one metallic layer or patch in intimate contact covering at least part of the surface of the substrate material. In addition, one or more intermediate structures, such as metalizing layers and polymer layers including adhesive layers, can be employed between the metallic layer or patch and the substrate material.

As used herein, the term “metallic coating” or “metallic layer” means a metallic deposit/layer applied to part of or the entire exposed surface of an article. The substantially porosity-free metallic coating is intended to adhere to the surface of the polymer substrate to provide mechanical strength, wear resistance, corrosion resistance, anti-microbial properties and a low coefficient of friction.

As used herein, the term “metal matrix composite” (MMC) is defined as particulate matter embedded in a fine-grained and/or amorphous metal matrix. MMCs are produced, e.g., by suspending particles in a suitable plating bath and incorporating particulate matter into the deposit by inclusion.

As used herein the term “chemical composition” means chemical composition of electrodeposit, the polymeric substrate or any intermediate layer.

As used herein the term “crystallinity in polymeric materials” is defined as the presence of a three-dimensional order on the level of atomic dimensions, and measured, e.g., by diffraction techniques, heat-of-fusion measurements, infrared spectroscopy or nuclear-magnetic resonance.

As used herein, the term “coating thickness” or “layer thickness” refers to depth in a deposit direction.

As used herein, the term “surface” means a surface located on a particular side of an article. A side of an article may include various surfaces or surface areas, including, but not limited to, a metallic article surface area, a polymer article surface area, a fastener surface area, a seam or joint surface area, etc. Thus, when indicating a coating is applied to a “surface” of an article, it is intended that such surface can comprise any one or all of the surfaces or surface areas located on that particular side of the article being coated.

As used herein the term “laminate” or “nanolaminate” means a metallic material that includes a plurality of adjacent layers that each has an individual thickness between 2 nm and 5 microns. A “layer” of a metallic material of a laminate or nanolaminate means a single thickness of a substance where the substance may be defined by a distinct composition, microstructure, phase, grain size, physical property, chemical property or combinations thereof. It should be appreciated that the interface between adjacent layers may not be necessarily discrte but may be blended, i.e., the adjacent layers may gradually transition from one of the adjacent layers to the other of the adjacent layers.

As used herein the term “graded material” means a material having at least one property in the deposition direction modified by at least 5%.

As used herein the term “compositionally modulated material” means a material whose chemical composition is continuously, periodically or abruptly altered in the deposition direction.

According to one aspect of the present disclosure, an article is provided by a process which comprises the steps of positioning the metallic or metallized work piece to be plated in a plating tank containing a suitable electrolyte and a fluid circulation system, providing electrical connections to the work piece/cathode to be plated and to one or several anodes and plating a structural layer of a metallic material on the surface of the metallic or metallized work piece using suitable direct current (D.C.) or pulse electrodeposition processes described, e.g., in the copending application U.S. Ser. No. 10/516,300 (2002) (DE 10,288,323; 2005).

The microstructure of the metallic material can be (i) crystalline with an average grain size of equal to or less than 10,000 nm, (ii) amorphous or (iii) contain both amorphous and fine-grained sections.

According to another aspect of the present disclosure, the metal coating may be applied to the polymer article in certain regions, by immersing the article partially into the plating solution, or by selectively masking areas of the article that need not be plated, or by co-molding the article with a plateable polymer (which corresponds to the region to be coated) and a non-plateable polymer (which corresponds to the region that is not to be coated), or by over-molding a plateable polymer layer on to a non-plateable polymer article

Metal-clad polymer articles of the present disclosure comprise, at least in part, fine-grained and/or amorphous metallic layers having a layer thickness of at least 0.001 mm, preferably more than 0.010 mm, preferably more than 0.02 mm, more preferably more than 0.03 mm and even more preferably more than 0.05 mm.

Articles of the present disclosure comprise a single or several fine-grained and/or amorphous metallic layers applied to the polymeric substrate as well as multi-layer laminates composed of alternating layers of fine-grained, amorphous and/or coarse-grained metallic layers.

The fine-grained metallic coatings/layers have a grain size under 5 μm (5,000 nm), preferably in the range of 2 to 1,000 nm, more preferably between 10 and 500 nm. The grain size can be uniform throughout the deposit; alternatively, it can consist of layers with different microstructure/grain size. Amorphous microstructures and mixed amorphous/fine-grained microstructures are within the scope of the present disclosure as well, as are graded and laminated metallic materials. Layering and/or grading the metallic layer by changing the composition, grain size or any other physical or chemical property is within the scope of this invention as well.

According to this disclosure, the entire polymer surface can be coated; alternatively, metal patches or sections can be formed on selected areas only (e.g., elbow regions of pipe connectors, etc., without the need to coat the entire article). Foam or honeycomb structures may also be selectively coated, i.e., within the structure, the outer surface, or both.

According to this disclosure metal patches or sleeves which are not necessarily uniform in thickness and/or microstructure can be deposited in order to, e.g., enable a thicker coating on selected sections or sections particularly prone to higher tensile or flexural stresses, such as elbow regions of pipe connectors, or regions prone to higher hoop stresses, such as in high burst pressure applications, etc.

The following listing further defines the laminate article/metal-clad article of the present disclosure:

TABLE 1
Metallic Coating/Metallic Layer Specification:

| | |
|---|---|
| Minimum yield stress, as measured by ASTM | 300; 500; 700 |
| E8 [MPa]: | |
| Minimum strain to yield, as measured by | 0.2; 0.4; 0.5; 0.6; 0.7; 0.8; 1.0 |
| ASTM E8 [%]: | |
| Maximum strain to yield, as measured by | 5; 10; 15; 20; 25; 30; 50 |
| ASTM E8 [%]: | |
| Minimum coefficient of liner thermal | −5; 0; 1 |
| expansion [10⁻⁶ K⁻¹] | |
| Maximum coefficient of liner thermal | 25; 30; 35; |
| expansion [10⁻⁶ K⁻¹] | |
| Microstructure: | Amorphous and/or crystalline |
| Minimum average grain size [nm]: | 1; 2; 5; 10 |
| Maximum average grain size [nm]: | 100; 500; 750; 1,000; 2,500; 5,000; |
| | 7,500; 10,000 |
| Metallic layer thickness minimum [μm]: | 1; 10; 25; 30; 50; 100 |
| Metallic layer thickness maximum [mm] : | 5; 25; 50 |
| Minimum sub layer or laminate layer | 2; 5; 10; 50; 100 |
| thickness [nm]: | |
| Maximum sub layer or laminate layer | 5; 25; 50 |
| thickness [mm]: | |
| Chemical composition (the specific material | Ag, Al, Au, Co, Cr, Cu, Fe, Ni, Mn, |
| contains at least one element selected from the | Mo, Pb, Pd, Pt, Rh, Ru, Sn, Ti, W, |
| group listed): | Zn and Zr |
| Other alloying additions (the specific material | B, C, H, N, O, P and S |
| contains at least one element selected from the | |
| group listed): | |
| Particulate additions (the specific material | metals (Ag, Al, In, Mg, Si, Sn, Pt, |
| contains at least one element selected from the | Ti, V, W, Zn); metal oxides (Ag₂O, |
| group listed): | Al₂O₃, SiO₂, SnO₂,TiO₂, ZnO); |
| | carbides of B, Cr, Bi, Si, W; carbon |
| | (carbon nanotubes, diamond, |
| | graphite, graphite fibers); glass; |
| | glass fibers; polymer materials |
| | (PTFE, PVC, PE, PP, epoxy resins) |
| Minimum particulate/fiber fraction [% by | 0; 1; 5; 10 |
| weight or volume] : | |
| Maximum particulate/fiber fraction [% by | 50; 75; 95; 99 |
| weight or volume] : | |
| Minimum average particulate particle size | 5; 50; 100; 500 |
| [nm] | |
| Maximum average particulate particle size | 25; 50; 100 |
| [micron] | |
| Minimum hardness [VHN]: | 25; 50; 100; 200; 400 |
| Maximum hardness [VHN] : | 800; 1,000; 2,000 |

TABLE 2
Polymeric Substrate Specification:

| | |
|---|---|
| Minimum ultimate tensile strength, | 100; 150; 200; 300 |
| as measured by ASTM D638 [MPa]: | |
| Minimum strain to failure, as | 0.75; 1.0; 1.5; 2.0 |
| measured by ASTM D638 [%]: | |
| Maximum strain to failure, as | 25; 30; 50; 75; 100; 150 |
| measured by ASTM D638 [%]: | |
| Minimum tensile strength at 0.4% | 30; 50; 60; 65; 70; 75; 80; 100; 125; 150; 175; |
| strain at room temperature [MPa] : | 200; |
| Minimum polymer crystallinity: | ≧0; ≧20%; ≧30%; ≧40%; ≧50%; |
| Polymer Glass transition | ≧75; ≧100; ≧150; ≧200 |
| temperature; As measured by ASTM | |
| E1356, [° C.] | |
| Composition (the specific material | unfilled or filled epoxy, phenolic and |
| contains at least one compound | melamine resins, polyester resins, urea resins; |
| selected from the group listed): | thermoplastic polymers such as thermoplastic |
| | polyolefins (TPOs) including polyethylene |
| | (PE) and polypropylene (PP); polyamides, |
| | mineral filled polyamide resin composites; |
| | polyphthalamides, polyphtalates, polystyrene, |
| | polysulfone, polyimides; neoprenes; |
| | polybutadienes; polyisoprenes; butadiene- |
| | styrene copolymers; poly-ether-ether-ketone |
| | (PEEK); poly-aryl ether ketones (PAEK), |
| | poly ether ketones (PEK), poly ether ketone |
| | ketones (PEKK) polycarbonates; polyesters; |
| | self-reinforcing polyphenylenes; poly-aryl |
| | amides (PARA) liquid crystal polymers such |
| | as partially crystalline aromatic polyesters |
| | based on p-hydroxybenzoic acid and related |
| | monomers; polycarbonates; chlorinated |
| | polymers such polyvinyl chloride (PVC); |
| | fluorinated polymers such as |
| | polytetrafluoroethylene (PTFE); and suitable |
| | blends of the above-mentioned polymers. |
| Polymer microstructure: | Crystalline; semi-crystalline; amorphous, |
| | including mixtures thereof |
| Polymer Fillers (the specific material | Metals and alloys comprising at least one |
| contains at least one element and/or | metal selected from the group consisting of |
| compound selected from the group | Ag, Al, In, Mg, Si, Sn, Pt, Ti, V, W, Zn; other |
| listed): | metal alloys such including steels and |
| | stainless steel; metal oxides (Ag₂O, Al₂O₃, |
| | SiO₂, SnO₂,TiO₂, ZnO); carbides of B, Cr, Bi, |
| | Si, W; carbon (carbon, carbon fibers, carbon |
| | nanotubes, diamond, graphite, graphite |
| | fibers); glass; glass fibers; fiberglass |
| | metallized fibers such as metal coated glass |
| | fibers; mineral/ceramic fillers such as talc, |
| | calcium silicate, silica, calcium carbonate, |
| | alumina, titanium dioxide, ferrite, mica and |
| | mixed silicates (e.g. bentonite or pumice), |
| | aramid fibers and particulates. |
| Minimum particulate/fiber fraction | 0; 1; 5; 10 |
| [% by volume]: | |
| Maximum particulate/fiber fraction | 50; 75; 95 |
| [% by volume]: | |

TABLE 3
Metal-clad Polymer Article Specification:

| | |
|---|---|
| Minimum stress before permanent deformation | 25; 50; 75; 100; 150; 275; 280; 290 |
| at room temperature [MPa]: | |
| Minimum stress before permanent deformation | 25; 50; 75; 100; 200; 225; 235; 255 |
| at 90° C. [MPa]: | |
| Minimum stress before permanent deformation | 25; 50; 75; 100; 200; 205; 215 |
| at 120° C. [MPa]: | |
| Minimum pull-off strength of the coating | 200; 300; 400; 600 |
| according to ASTM D4541-02 Method A-E | |
| [psi]: | |
| Maximum pull-off strength of the coating | 2,500; 3,000; 6,000 |
| according to ASTM D4541-02 Method A-E | |
| [psi]: | |
| Minimum metal volume fraction: [%]: | 0.1; 0.25; 0.5; 1 |
| Maximum metal volume fraction: [%]: | 25; 50; 75; 95; 99 |
| Increase in stiffness (flexural, tensile or | 10; 20; 50; 100; 200; 500; |
| torsional) of metal-clad polymer over polymer | |
| alone, measured at room temperature [%]: | |
| Increase in strength (bend and tensile) for the | 10; 20; 50; 100; 200 |
| range of metal-cladding volume fractions | |
| specified), measured at room temperature [%]: | |
| Increase in strength (bend and tensile) for the | 10; 20; 50; 100; 200 |
| range of metal-cladding volume fractions | |
| specified), , measured at (−40, 50, 100, 150 and | |
| 200° C. [%]: | |
| Minimum density [g/cm³] | 1; 1.25; 1.50; 1.75; 2; 2.25; 2.5 |
| Maximum density [g/cm³] | 4; 4.5; 5; |

### BRIEF DESCRIPTION OF THE DRAWINGS

In order to better illustrate the present disclosure by way of examples, descriptions are provided for suitable embodiments of the method/process/apparatus according to the present disclosure in which:

FIG. 1 shows stress-strain curves of a polymer and a metallic material to illustrate how to determine the design ratio in a metal-polymer article using the inventive design concept.

FIG. 2 shows a process flow chart for determining the design criteria according to one aspect of the present disclosure.

FIG. 3 shows stress-strain curves of various polymer materials of interest.

### DETAILED DESCRIPTION

The present disclosure relates to high yield strength polymer-metal hybrid materials comprising polymeric materials and one or more high strength, fine-grained and/or amorphous, metallic materials, wherein the material combinations are chosen such that the resulting polymer-metal hybrid materials exhibit higher strengths at lower thicknesses of the clad metal, and thereby lower weight. The metallic materials/coatings are fine-grained and/or amorphous and are produced by DC or pulse electrodeposition, electroless deposition, physical vapor deposition (PVD), chemical vapor deposition (CVD) and gas condensation or the like. Such inventive metal-clad polymer articles utilize the load bearing capacity of both the metallic and the polymeric materials to a greater extent on loading, and are suitable for structural applications.

Applying metallic coatings to polymer and polymer composite parts is in widespread use in consumer and sporting goods, automotive and aerospace applications. Polymer composites with carbon/graphite and/or glass fibers are relatively inexpensive, easy to fabricate and machine; however, they are not very durable. Metallic coatings are therefore frequently applied to polymers and polymer composites to achieve the required mechanical strength, wear and erosion resistance and to obtain the desired durability and service life.

The person skilled in the art of plating will know how to electroplate or electroless plate selected fine-grained and/or amorphous metals, alloys or metal matrix composites choosing suitable plating bath formulations and plating conditions. Similarly, the person skilled in the art of PVD, CVD and gas condensation techniques will know how to prepare fine-grained and/or amorphous metal, alloy or metal matrix composite coatings.

One An important design aspect for structural components with metal coated polymers, and broadly, for most composites, is to normalize the mechanical properties of the hybrid materials to their weight, e.g., the specific tensile strength of the material is its strength per unit weight. The present disclosure focuses on the selection of the optimal metal and polymer combination to achieve components with an enhanced high load bearing capability with respect to weight. Thus, important components of the present disclosure are: a high yield strength metallic coating and a stiff enough polymer that will carry high loads when the metal coating reaches its yield point, thereby taking advantage of the properties of both materials. More specifically, the material selection is defined as the combination of metallic and polymeric materials which result in an enhancement in the load bearing capacity of the hybrid material at a lower thickness of the clad metal, and thereby a lower weight.

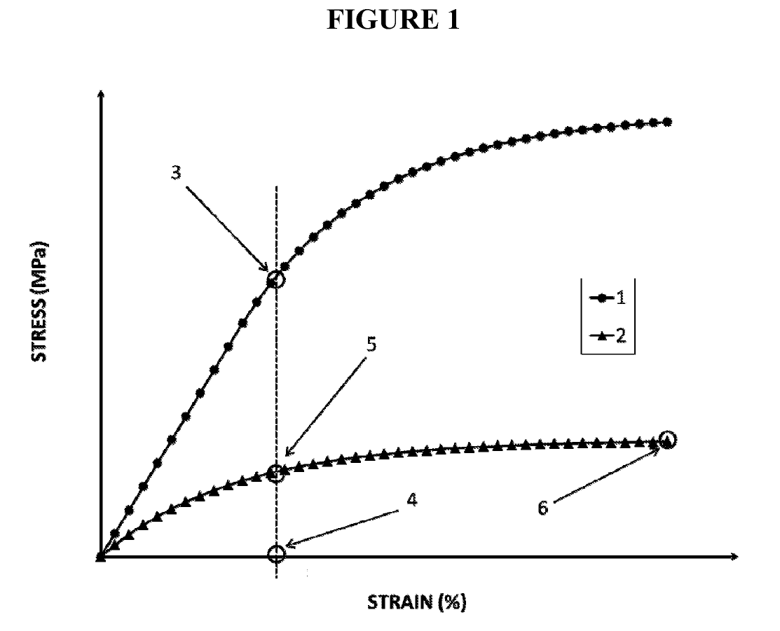

The inventive criterion for material selection is defined as the ratio of the stress on the polymer, at the yield strain of the metallic coating, to the ultimate tensile strength of the polymer. FIG. 1 illustrates an exemplary method for determining the design ratio for the polymer selection, in a metal-polymer article and details the methodology for determining the stress on the polymer at the yield strain of the metallic coating. The methodology relies on the stress-strain curves of the two components, the polymer (identified by the triangular symbols), as well as the fine-grained metallic material (identified by the circular symbols). The person skilled in the art will understand that in the case of non-uniform metal or polymer structures including, but not limited to, graded structures and laminates the appropriate stress-strain curves for the metallic component(s) as well as the polymer component(s) need to be determined over the operating temperature range in order to appropriately determine the design. FIG. 1 depicts the stress strain curve obtained in the tensile mode but the person skilled in the art will understand stress-strain curves can be obtained in the tensile and compressive mode.

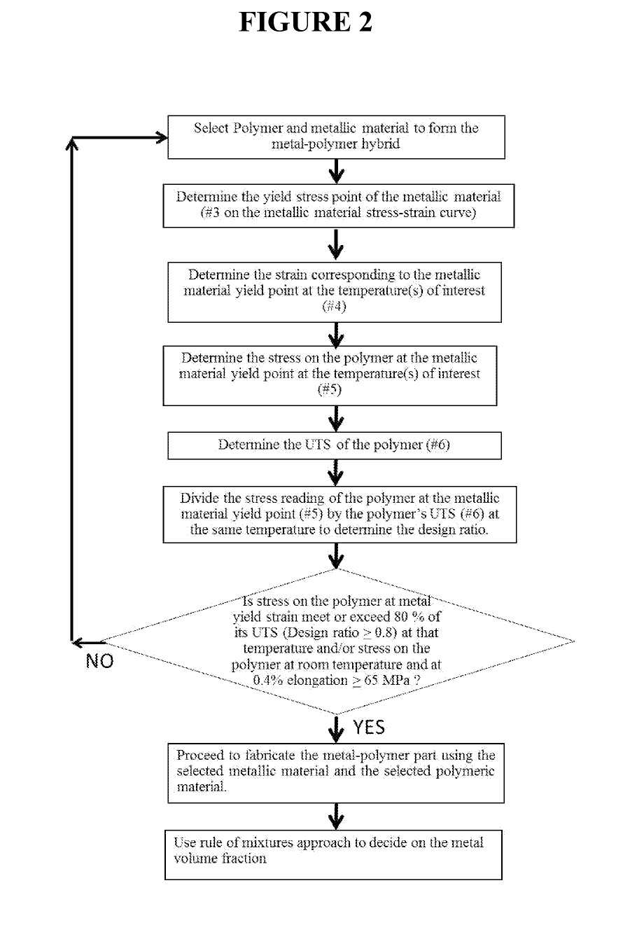

Once these stress-strain curves for the metallic material (reference numeral 1) and polymer (reference numeral 2) are obtained over the temperature(s) or temperature range of interest, the inventive steps to be followed are (as illustrated in FIG. 2):
(i) Determine the yield stress point of the metallic material (reference numeral 3 on the metallic material stress-strain curve).
(ii) Determine the strain corresponding to the metallic material yield point at the temperature(s) of interest (reference numeral 4).
(iii) Determine the stress on the polymer at the metallic material yield point at the temperature(s) of interest (reference numeral 5).
(iv) Determine the UTS of the polymer (reference numeral 6).
(v) Divide the stress reading of the polymer at the metallic material yield point (reference numeral 5) by the polymer's UTS (reference numeral 6) at the same temperature to determine the design ratio.
(vi) The stress on the polymer at this point (the design criteria) needs to meet or exceed a minimum specified percentage of its UTS at that temperature as highlighted in the objectives set forth above and/or the stress on the polymer at room temperature and at 0.4% elongation needs to meet or exceed a specified design target as also highlighted in the objectives set forth above.
(vii) If the selected polymer-metallic material combination does not meet the design criteria repeat all steps for another polymer until a polymer is identified which meets or exceeds the design criteria.
(viii) If the selected polymer meets or exceeds the design criteria proceed to fabricate the metal-polymer part using the selected metallic material and the selected polymeric material.
(ix) Divide the stress reading of the polymer at the metallic material yield point (reference numeral 5) by the sum of the polymer stress at the metallic material yield point (reference numeral 5) and the metallic material yield stress (reference numeral 3) to determine the relative contribution of the polymer to the article before deformation/failure occurs for articles of equal metal and polymer thickness.
(x) Revise the metallic material yield stress (reference numeral 3) and the polymer stress at the metallic material yield point (reference numeral 5) depending on the relative thickness of the two materials using the “rule of mixtures” to determine the expected yield stress of the article and verify experimentally.

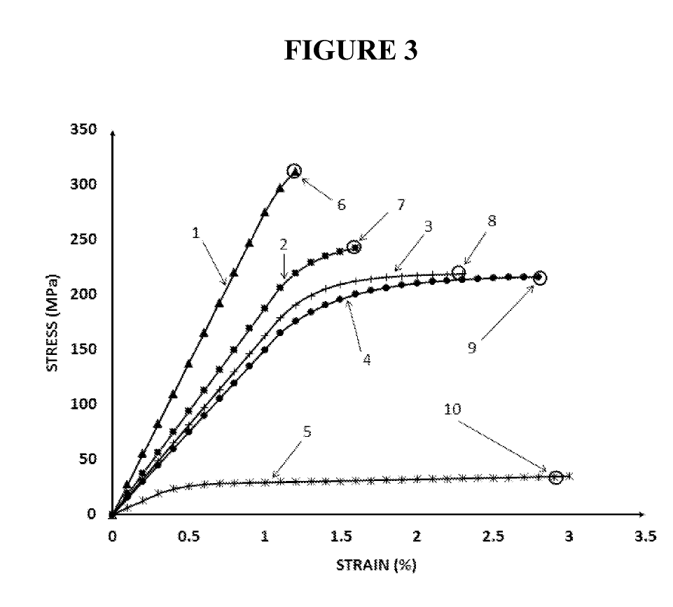

FIG. 3 highlights stress-strain curves for several polymers at room temperature (e.g., 23° C.), including PEEK 90HMF40 (reference numeral 1); PEEK 450CA30 (reference numeral 2); polyimide (Vespel TP8130) (reference numeral 3); Glass Filled Nylon (Durethan BKV 130) (reference numeral 4) and ABS (Cyclolac MG37EP) (reference numeral 5) and their respective UTS values (reference numerals 6-10).

As highlighted, the determination of design ratios for the various material combinations, as taught by the present disclosure, comprises three steps: (i) obtain the stress-strain curves for the polymers from polymer resin suppliers; (ii) from the stress-strain curves, determine the stress on the polymers σₚ₀, at the yield strain (i.e., elastic limit) of the metallic material of interest; (ii) determine the design ratio, which is the ratio of σₚ₀ to the ultimate tensile strength of the polymer.

Table 4 highlights the grain size, density, the elastic limit and the yield stress for selected metallic materials of interest.

TABLE 4
Selected Properties of Metallic Materials

| | | | STRAIN AT YIELD | YIELD STRESS | |
|---|---|---|---|---|---|
| | GRAIN | | BETWEEN | BETWEEN | |
| | SIZE | DENSITY | 23-120° C. | 23-120° C. | |
| METAL TYPE | [nm] | [g/cm³] | [%] | [MPa] | SUPPLIER |
| Conventional | >10,000 | 8.9 | 0.25 | 490 | Enthone Inc., |
| Coarse-grained | | | | | 350 Frontage |
| Sulfamate Ni | | | | | Road |
| | | | | | West Haven, CT |
| | | | | | 06516, USA |
| Ultra-fine-grained | 150 | 8.9 | 0.4 | 670 | Integran |
| Ni | | | | | Technologies, 1 |
| | | | | | Meridian Rd., |
| | | | | | Toronto ON |
| | | | | | M9W4Z6, |
| | | | | | Canada |
| Nanocrystalline | 15 | 8.9 | 0.5 | 790 | Integran |
| Ni | | | | | Technologies, 1 |
| | | | | | Meridian Rd., |
| | | | | | Toronto ON |
| | | | | | M9W4Z6, |
| | | | | | Canada |
| Ultra-fine-grained | 300 | 8.9 | 0.6 | 550 | Integran |
| Cu | | | | | Technologies, 1 |
| | | | | | Meridian Rd., |
| | | | | | Toronto ON |
| | | | | | M9W4Z6, |
| | | | | | Canada |
| Nanocrystalline | 20 | 8.3 | 1.0 | 1100 | Integran |
| Ni—20Fe | | | | | Technologies, 1 |
| | | | | | Meridian Rd., |
| | | | | | Toronto ON |
| | | | | | M9W4Z6, |
| | | | | | Canada |
| Nanocrystalline | 15 | 8.7 | 1.2 | 1500 | Integran |
| Co—2P | | | | | Technologies, 1 |
| | | | | | Meridian Rd., |
| | | | | | Toronto ON |
| | | | | | M9W4Z6, |
| | | | | | Canada |

Table 5 shows the room temperature tensile strength values for selected polymer/metal combinations and the resulting design ratio.

TABLE 5

| | Polymer tensile | | Metal |
|---|---|---|---|
| | strength at metal | | volume |
| Polymer-Metallic | yield | Design | fraction |
| Material combination | σₚ₀ (MPa) | Ratio | (%) |
| PEEK 450CA30 + Integran | 225 | 0.94 | 5 |
| fine grained cobalt alloy | | | |
| PEEK 450CA30 + Integran | 218 | 0.91 | 5 |
| fine grained nickel-iron | | | |
| PEEK 450CA30 + Conventional | 70 | 0.29 | 5 |
| coarse grained sulfamate nickel | | | |
| PEEK 90HMF40 + Integran | 285 | 0.86 | 5 |
| fine grained nickel-iron | | | |
| PEEK 90HMF40 + Integran | 310 | 0.94 | 5 |
| fine grained cobalt alloy | | | |
| PEEK 90HMF40 + conventional | 105 | 0.32 | 5 |
| coarse grained sulfamate nickel | | | |
| Vespel TP8130 PI + Integran | 210 | 0.96 | 5 |
| fine grained cobalt alloy | | | |
| Durathan PA + Integran | 170 | 0.78 | 5 |
| fine grained cobalt alloy | | | |
| Durathan PA + Integran | 158 | 0.73 | 5 |
| fine grained nickel-iron | | | |
| Durathan PA + conventional | 48 | 0.22 | 5 |
| coarse grained sulfamate nickel | | | |
| ABS + Integran fine | 15 | 0.42 | 5 |
| grained nickel-iron | | | |
| ABS + Integran fine | 15 | 0.42 | 5 |
| grained nickel | | | |
| ABS + conventional | 10 | 0.28 | 5 |
| coarse grained sulfamate nickel | | | |

Although the methodology for determining the design ratio was illustrated at ambient temperature, the usefulness of the design ratio concept can be applied at all temperatures, including at elevated temperatures, with similar results.

Polymeric substrates, for the most part, have a coefficient of linear thermal expansion (CLTE) significantly exceeding 25×10⁻⁶K⁻¹ whereas metallic materials typically have a CLTE below 35×10⁻⁶K⁻¹. Selected polymeric materials and particularly filled or reinforced polymeric materials, can display coefficient of thermal expansion values which are not isotropic, but vary significantly with the direction. Due to the CLTE mismatch between the metallic coating and the substrate as well as to share the load put onto the article in service, the bond strength between the coating and the substrate needs to be sufficiently high to prevent delamination. To clarify, the stronger the bond strength between the polymer and the metallic material the more CLTE mismatch and the higher the temperature fluctuations the metal-clad polymer article can endure and ensure the load carrying capability is shared by the polymer and then metal. It is therefore important to suitably roughen/pretreat/activate the polymeric surface to ensure the bond strength to the coatings and particularly metallic coatings is optimized as taught in Tomantschger in US 2010/0304065, assigned to the same assignee as the present application, and is hereby included in its entirety. The person skilled in the art knows that the specific pretreatment conditions need to be optimized for each polymer and molded part to maximize the bond strength which can be conveniently determined using the pull off test described (ASTM D4541-02 Method A-E).

Crystallinity in polymeric materials is an important factor in determining the performance of the polymers during long-term exposure to loads, as well as exposure to elevated temperatures. The degree of crystallinity is measured as the fraction of mass or volume of the crystalline phase with respect to the entire polymer. Generally, crystalline and/or semi-crystalline polymers tend to have a higher fatigue and creep-resistance when compared to amorphous polymers, but they also have a higher chemical or solvent resistance, and are very difficult to bond to other materials. They are, however, also difficult to process in terms of dimensional stability during molding. Hence, specific molding, activation and metallization techniques need to be used in order to apply the metallic coatings on to these polymers. Therefore, the metal-clad polymer articles described by this disclosure contain polymeric substrates that are, at least in part, crystalline. The polymer and metallic materials are selected to ensure the maximum strain on the polymer is always greater than the maximum strain at which the metal deforms permanently.

Furthermore, additional processing requirements will be placed on crystalline and/or semi-crystalline polymers that contain any of the previously mentioned filler materials. Typically, it is desired that the filler materials are homogeneously distributed throughout the polymer matrix. However, in many cases, the fillers may be distributed unevenly through the bulk of the matrix so as to form a non-isotropic polymeric substrate, in order to impart certain properties to the polymeric substrate. For example, in glass-filled polymeric substrates which are to be used for metal-clad articles, the molding process conditions may be tailored in order to achieve a glass-fiber free, resin rich surface, ranging from 0.1 to 10 microns deep, in order to achieve better adhesion of the metal layer to the substrate, while the remainder of the substrate may be uniformly filled with glass fibers. Conversely, the surface of the polymer article may contain an excess of mineral fillers compared with the bulk, which are then etched away to create keyholes which may aid the adhesion of the metal layer to the polymeric article or substrate.

Another way of improving the platability of crystalline and/or semi-crystalline polymers is to use a process by which the surface layer is molded with an amorphous polymer, which exhibits low solvent resistance, thereby enhancing the chances of forming the mechanical keyholes in the surface layer, leading to a higher adhesion; while beneath the surface layer, the crystalline polymer of choice is present. Thus, a two-layered polymeric substrate or article can first be prepared, over which the metallic coating is formed.

One or more metallic coating layers of a single or several chemistries and microstructures can be employed. Metallic layer(s) can be suitably graded. In case of multiple layers such laminates may be of the same metal or alloy, but with differing physical or mechanical properties. The multiple layers may also be of alloys, but with differing alloy compositions. The multiple layers may also be of different metals or different alloys. In addition to the high strength and stiffness benefits that may be attained, the multiple layers in the coating may be applied to enhance the coating's functional properties such as corrosion resistance. Alternatively, the multiple layers may also enhance the aesthetic appearance of a part or object to be coated.

When multiple layers of metallic materials are coated on a polymeric substrate that may also contain multiple layers, the same methodology for calculating the design ratio as in a single layer is used, except that in this case, the metallic layer and the polymer layer that have the most strength bearing capabilities are chosen for the calculations or, alternatively, the properties of the metallic material and the polymer substrate are averaged. In the case where there are more than one layer in the metal coating and more than one layer in the polymer substrate, that contribute significantly in terms of strength or stiffness, a rule of mixtures approach can be followed, replacing the multiple metal layers and/or the multiple polymer layers with an effective metal layer and/or an effective polymer layer.

The single or multiple layers of the metallic coating may be applied to the article or part, as a whole, or in selected regions/segments/patches of the article. The metal coating may be applied to the polymer article in certain regions, by immersing the article partially into the plating solution, or by selectively masking areas of the article that need not be plated, or by co-molding the article with a plateable polymer (which corresponds to the region to be coated) and a non-plateable polymer (which corresponds to the region that is not to be coated). Alternatively, the metallic material can be electroformed first and the polymer material can be applied to at least part of the metallic material.

The metallic coating can be suitably exposed to a finishing treatment, which can include, among others, electroplating, i.e., chromium or tin plating and/or applying a polymeric material, i.e., paint or adhesive.

The present disclosure is illustrated by the following working example.

### WORKING EXAMPLE

### High Tensile Strength Metal-Polymer Hybrid Article

An aerospace connector body made out of 6061-T6 grade Aluminum, or CP grade 2 Titanium, having an operating temperature range of −40° C. to 120° C. was selected for replacement with a metal-polymer hybrid material. The desired article is required to withstand at least the tensile strength of the aluminum part at a maximum operating temperature of 120° C. and weigh no more than the aluminum part. Five polymers and three metallic coatings were evaluated for the application. The three metallic coatings selected included conventional coarse-grained sulfamate nickel (grain size >10 microns); Integran's nanocrystalline Ni-20Fe (grain size 20 nm); and Integran's nanocrystalline Co-2P (grain size 15 nm). Selected material properties of the metallic materials are shown in Table 4 and Table 6 shows selected properties of the polymers.

TABLE 6
Selected Properties of Polymer Substrates

| | | | | ULTIMATE | ULTIMATE | |
|---|---|---|---|---|---|---|
| | | | | TENSILE | TENSILE | |
| | | TENSILE | | STRENGTH | STRENGTH | |
| | | STRENGTH | ULTIMATE | AT 90° C. | AT 120° C. | |
| | | AT 23° C. | TENSILE | [MPa] AND | [MPa] AND | |
| | | And 0.4% | STRENGTH | FRACTION | FRACTION | |
| | DENSITY | STRAIN | AT 23° C. | OF RT UTS | OF RT UTS | |
| POLYMER | [g/cm³] | [MPa] | [MPa] | [%] | [%] | SUPPLIER |
| PEEK 450 | 1.49 | 75 | 240 | 220/92 | 180/75 | Victrex |
| CA30 (30% | | | | | | PLC, |
| carbon | | | | | | Thornton |
| filled | | | | | | Cleveleys |
| PEEK) | | | | | | Lancashire |
| | | | | | | FY5 4QD, |
| | | | | | | UK |
| PEEK | 1.45 | 110 | 330 | 290/88 | 230/70 | Victrex |
| 90HMF40 | | | | | | PLC, |
| (40% | | | | | | Thornton |
| carbon | | | | | | Cleveleys |
| filled | | | | | | Lancashire |
| PEEK) | | | | | | FY5 4QD, |
| | | | | | | UK |
| Vespel | 1.42 | 65 | 218 | 182/90 | 148/73 | DuPont |
| TP8130 | | | | | | Engineering |
| (carbon | | | | | | Polymers |
| filled | | | | | | Pencader |
| polyimide | | | | | | Site |
| | | | | | | Newark, DE |
| | | | | | | 19714, USA |
| Durethan | 1.34 | 60 | 217 | 126/58 | 97/45 | PolyOne |
| BKV130 | | | | | | Canada |
| (30% glass | | | | | | 5915 |
| filled | | | | | | Airport |
| Nylon) | | | | | | Road, Suite |
| | | | | | | 425 |
| | | | | | | Mississauga, |
| | | | | | | ON, L4V |
| | | | | | | 1T1, Canada |
| Cycolac | 1.04 | 25 | 35 | n/a | n/a | SABIC |
| MG37EP | | | | | | Americas |
| ABS | | | | | | 2500 City |
| | | | | | | West |
| | | | | | | Boulevard, |
| | | | | | | Suite 650, |
| | | | | | | Houston, |
| | | | | | | TX, 77204 |
| | | | | | | USA |

The tensile strength and density (weight per unit volume) for all hybrid material samples were determined by coupon testing. Specifically, the polymer coupons were tensile bars injection-molded according to ASTM 638 dimensions (15 cm×1.2 cm×0.32 cm). Metallic coatings were applied to the polymer substrates through a three-step coating procedure, namely, (i) the polymer substrates were first etched in a chromo—sulphuric etch, then metalized with a thin layer of electroless nickel coating from processes and chemicals provided by MacDermid Inc, (245 Freight St., Waterbury, Conn. 06702, USA) to achieve an average metal thickness of 0.4-2.0 microns; (ii) a coating of copper with a thickness between 10-30 microns was applied on the electroless nickel layer, through an electrodeposition process, to enhance conductivity of the electroless nickel coated polymeric substrate; and (iii) the coarse-grained Ni as well as fine-grained Co alloy, or Ni—Fe coatings were applied to achieve a metal volume fraction of 5%.

The sulfamate nickel coating was applied using the process conditions and chemicals provided by Enthone Inc. The nanocrystalline Co alloy and nickel-iron (Ni—20Fe) coatings were applied using the process conditions and chemicals provided by Integran Technologies Inc. (1 Meridian Road, Toronto, Ontario, Canada M9W 4Z6). The tensile bars were loaded to a maximum strain corresponding to yield strain of the metal (0.25% for the sulfamate Ni, 1.0% for the fine grained Ni—20Fe and 1.2% for the nanocrystalline Co—1.8% P), using an Instron, model 3360, equipped with a 5 kN load cell, operated through the computer using the Bluehill software from Instron Corp. A loading rate of 25 mm/min was used. For elevated temperature testing, a furnace was attached to the Instron. The samples were loaded at room temperature, and the furnace temperature was increased to the desired test temperature. The samples were then equilibrated at the test temperature for 30 minutes, before the start of the test.

Table 7 compares the maximum tensile stress reached by the metal-clad polymer tensile bars containing 5 vol % metal, at ambient as well as elevated temperatures, as well as the density of the metal-clad bars, with that of aluminum. The results illustrate that, of all polymer/metal combinations, only the PEEK and Vespel polymers when combined with Integran's fine-grained metallic coatings (5% volume fraction of metal) using the inventive polymer substrate/metal matching procedure described meets or exceeds the original Al part specification on strength and weight over the operating temperature range.

TABLE 7
Comparison of Maximum Stress and Density of Metal-
Clad Polymer Bars With Aluminum and Titanium

| | | | Max. tensile | Max. tensile | Max. tensile |
|---|---|---|---|---|---|
| | Metal | | stress before | stress before | stress before |
| | Volume | Average | the sample part | the sample | the sample |
| | fraction | Density | yields at | part yields at | part yields at |
| Sample Material | [%] | [g/cm³] | 23° C. [MPa] | 90° C. [MPa] | 120° C. [MPa] |
| 6061-T6 Aluminum | N/A | 2.7 | 290 | 255 | 215 |
| CP grade 2 Titanium | N/A | 4.5 | 280 | 224 | 207 |
| PEEK 90HMF40 + | 5% | 1.81 | 364 | 336 | 292 |
| Integran | | | | | |
| nanocrystalline Co2P | | | | | |
| (this invention) | | | | | |
| PEEK 90HMF40 + | 5% | 1.79 | 321 | 294 | 272 |
| Integran | | | | | |
| nanocrystalline | | | | | |
| Ni20Fe (this invention) | | | | | |
| PEEK 450 CA30 + | 5% | 1.85 | 303 | 284 | 246 |
| Integran | | | | | |
| nanocrystalline Co2P | | | | | |
| (this invention) | | | | | |
| PEEK 450 CA30 + | 5% | 1.83 | 295 | 279 | 226 |
| Integran | | | | | |
| nanocrystalline | | | | | |
| Ni20Fe | | | | | |
| (this invention) | | | | | |
| Vespel | 5% | 1.78 | 297 | 262 | 221 |
| TP8130 + Integran | | | | | |
| nanocrystalline Co—2P | | | | | |
| (this invention) | | | | | |
| Durethan BKV130 + | 5% | 1.70 | 275 | 192 | 167 |
| Integran | | | | | |
| nanocrystalline Co2P | | | | | |
| Durethan BKV130 + | 5% | 1.69 | 260 | 175 | 147 |
| Integran | | | | | |
| nanocrystalline | | | | | |
| Ni20Fe | | | | | |
| PEEK450CA30 + | 5% | 1.86 | 267 | 233 | 195 |
| Conventional coarse | | | | | |
| grained sulfamate Ni | | | | | |
| Cycolac MG37EP + | 5% | 1.40 | 76 | N/A | N/A |
| Integran | | | | | |
| nanocrystalline | | | | | |
| Ni20Fe | | | | | |
| Durethan BKV130 + | 5% | 1.73 | 230 | 144 | 116 |
| conventional coarse | | | | | |
| grained sulfamate Ni | | | | | |
| Cycolac MG37EP + | 5% | 1.43 | 31 | N/A | N/A |
| conventional coarse | | | | | |
| grained sulfamate Ni | | | | | |

The various combinations of metal-polymer hybrid had an average specific gravity between 1.78 and 1.85, whereas the aluminum article has a specific gravity of 2.7, and the titanium article, which has a specific gravity of 4.5. The data show that the inventive metal-clad polymer articles are about 30% lighter than the aluminum article, and 60% lighter than the titanium article while providing superior mechanical performance as defined as the maximum tensile stress before permanent deformation of the article occurs over the entire operating temperature range. The example illustrates that a judicious selection of the polymer substrate and the metal coating, as prescribed by this disclosure, can be used to obtain the mechanical requirements of the original aluminum part with a distinct weight advantage.

Similar high-strength metal-clad polymer articles are obtained when the metallic material contains at least one component selected from the group consisting of compositionally modulated materials, graded, layered structures, laminates and nanolaminates.

The foregoing description of the present disclosure has been presented describing certain operable and preferred embodiments. It is not intended that the present disclosure should be so limited since variations and modifications thereof will be obvious to those skilled in the art, all of which are within the spirit and scope of the present disclosure and are also intended to be encompassed by the following claims.

1. A metal-clad polymer article comprising:
a polymeric material with or without particulate addition, said polymeric material defining a permanent substrate;
a metallic material covering at least part of a surface of said polymeric material, said metallic material having a microstructure which, at least in part, is at least one of fine-grained with an average grain size between 2 and 5,000 nm and amorphous, said metallic material having an elastic limit between 0.2% and 15%;
with or without at least one intermediate layer between said polymeric material and said metallic material; and
wherein a stress on said polymeric material, at a selected operating temperature, reaches at least 60% of its ultimate tensile strength at a strain equivalent to the elastic limit of said metallic material.

2. An article according to claim 1, wherein said operating temperature is between approximately −65° C. and approximately 200° C.

3. An article according to claim 1, wherein said operating temperature is room temperature, said polymeric material is selected to reach at least 80% of its ultimate tensile strength at the strain equivalent of the elastic limit of said metallic material.

4. An article according to claim 1, wherein the article has an average density in the range of 1 to 4.5 g/cm³ and, at room temperature, has a stress of at least 280 MPa before the article yields and irreversible deforms.

5. An article according to claim 1, wherein said at least one intermediate layer is selected from the group consisting of a metallic intermediate layer, a polymeric adhesive intermediate layer and a conductive polymeric intermediate layer containing conductive particulates.

6. An article according to claim 5, wherein at least one of said intermediate conductive layer comprises a metallic layer having one or more metals selected from the group consisting of Ag, Cu and Ni or an alloy containing at least two of the metals from the group.

7. An article of claim 1, wherein the article, at room temperature, has a yield strength of at least 100 MPa.

8. An article of claim 1, wherein the article has a pull-off strength between the polymeric material and the metallic material and between the at least one intermediate layer and the metallic material exceeding 200 psi as determined by ASTM D4541-02 Method A-E.

9. An article according to claim 1, wherein said metallic coating is selected from the group of:
(i) one or more metals selected from the group consisting of Ag, Al, Au, Co, Cr, Cu, Fe, Ni, Mn, Mo, Pd, Pt, Rh, Ru, Sn, Ti W, Zn and Zr,
(ii) pure metals or alloys containing at least two of the metals listed in (i), further containing at least one element selected from the group of B, C, H, O, P and S;
(iii) any of (i) or (ii) where said metallic coating also contains particulate additions in the volume fraction between 0 and 95% by volume.

10. An article according to claim 9, wherein said metallic material contains particulate addition and said particulate addition is of one or more materials which is a metal selected from the group consisting of Ag, Al, Cu, In, Mg, Si, Sn, Pt, Ti, V, W, Zn; a metal oxide selected from the group consisting of Ag₂O, Al₂O₃, SiO₂, SnO₂, TiO₂, ZnO; a carbide of B, Cr, Bi, Si, W; carbon selected from the group consisting of carbon nanotubes, diamond, graphite, graphite fibers; ceramic, glass; and polymer material selected from the group consisting of PTFE, PVC, PE, PP, ABS, epoxy resin.

11. An article according to claim 1, wherein said metallic material is selected to comprise at least one material selected from the group consisting of a monolithic material, a graded material, and a multi-layer laminate.

12. An article according to claim 1, comprising a polymeric material selected from the group consisting of epoxy resins, phenolic resins, polyester resins, urea resins, melamine resins, thermoplastic polymers, polyolefins, polyethylenes, polypropylenes, polyamides, poly-ether-ether-ketones, poly-aryl-ether-ketones, poly ether ketones, poly-ether-ketone-ketones, mineral filled polyamide resin composites, polyphthalamide, polyphtalates, polystyrene, polysulfone, polyimides, neoprenes, polyisoprenes, polybutadienes, polyisoprenes, polyurethanes, butadiene-styrene copolymers, chlorinated polymers, polyvinyl chloride, fluorinated polymers, polytetrafluoroethylene, polycarbonates, polyesters, liquid crystal polymers, partially crystalline aromatic polyesters based on p-hydroxybenzoic acid, polycarbonates, acrylonitrile-butadiene-styrene their copolymers and their blends.

13. An article according to claim 12, wherein said polymeric material consists of at least one of glass fibers or a carbon-containing material selected from the group consisting of graphite, graphite fibers, carbon, carbon fibers and carbon nanotubes.

14. An article according to claim 1, comprising at least one polymeric material selected from the group consisting of poly-ether-ether-ketones, poly-aryl-ether-ketones and polyimides, and poly ether ketones, poly ether ketone ketones, and their blends.

15. An article according to claim 1, wherein said metallic material represents between 1% and 50% of the total weight of the article.

16. An article according to claim 1, wherein said article at least partially includes a generally tubular structure and said fine-grained metallic material extends over at least part of one of an inner surface or and outer surface of said generally tubular structure.

17. An article according to claim 1, wherein said metallic material has a thickness between 10 and 500 microns.

18. An article according to claim 1, including said at least one intermediate layer between said polymeric material and said metallic material, said at least one intermediate layer being electrically conductive and including at least one material selected from the group consisting of Cu, Ni, Ag and carbon.

19. A metal-clad polymer article comprising:
a polymeric material with or without particulate addition, said polymeric material defining a permanent substrate;
a metallic material covering at least part of a surface of said polymeric material, said metallic material having a microstructure which, at least in part, is at least one of fine-grained with an average grain size between 2 and 5,000 nm and amorphous;
with or without at least one intermediate layer between said polymeric material and said metallic material; and
wherein, at room temperature, a stress on said polymeric material at a strain of 0.4% is at least 65 MPa.

20. An article according to claim 19, wherein a stress on said polymeric material reaches at least 200 MPa at a strain of 0.4%.

21. An article according to claim 19, wherein said metallic material is selected to comprise at least one material selected from the group consisting of a monolithic material, a graded material, and a multi-layer laminate.

22. A method for preparing a metal-clad polymer article comprising:
providing a metallic material having a microstructure which, at least in part, is at least one of fine-grained with an average grain size between 2 and 5,000 nm and amorphous;
selecting a polymeric material which, at the strain equivalent to the elastic limit of the metallic material, has a yield stress of at least 60% of the ultimate tensile strength of the polymeric material at a predetermined operating temperature; and
applying the metallic material to at least part of the polymeric material to form a light-weight article.

23. A method according to claim 22, where the yield stress on the polymeric material at the elastic limit of the metallic material is at least 80% of the ultimate tensile strength of the polymeric material.

24. A method according to claim 22, further comprising depositing said metallic layer onto said polymeric material by one of electroless depositions, electrodeposition, physical vapor deposition (PVD), and chemical vapor deposition (CVD).

25. A method according to claim 22, further comprising:
determining the elastic limit of the metallic material,
determining the strain of the polymeric material corresponding to the elastic limit of the metallic material at the predetermined operating temperature,
determining the stress on the polymeric material at the elastic limit of the metallic material at the predetermined operating temperature,
determining the ultimate tensile strength of the polymeric material at the predetermined operating temperature, and
determining a design ratio by dividing the determined stress of the polymeric material by the ultimate tensile strength of the polymeric material.

26. The method according to claim 25, further comprising selecting a polymeric material having a yield stress greater than or equal to a predetermined percentage of the design ratio.

27. The method according to claim 25, further comprising selecting a polymeric material having a stress on the polymeric material at a strain of 0.4% being at least 65 MPa.
